(19) United States
(12) Patent Application Publication
(10) Pub. No.: US 2022/0416108 A1
(43) Pub. Date: Dec. 29, 2022

(54) Optical Receiving Device and Manufacturing Method Therefor

(71) Applicant: Nippon Telegraph and Telephone Corporation, Tokyo (JP)

(72) Inventors: Yoshiho Maeda, Tokyo (JP); Tatsuro Hiraki, Tokyo (JP); Hiroshi Fukuda, Tokyo (JP)

(21) Appl. No.: 17/777,893

(22) PCT Filed: Nov. 20, 2019
(86) PCT No.: PCT/JP2019/045376

§ 371 Date: May 18, 2022

(51) Int. Cl. H01L 31/105; G02B 6/13; H01L 31/0304; H01L 31/18

(52) U.S. Cl. CPC H01L 31/105; G02B 6/13; H01L 31/03046; H01L 31/1844; G02B 2006/12078

(57) ABSTRACT

A light reception device of the present invention includes a first i-type cladding region, an n-type waveguide core having a predetermined width, and a second i-type cladding region in contact with a side surface of the n-type waveguide core on a substrate, includes a p-type absorption layer, a p-type diffusion barrier layer, a p-type contact layer, and a p-type electrode formed in an upper part above a region including a part of the n-type waveguide core, with an i-type insertion layer interposed between the upper part and the region, and includes an n-type electrode on an upper surface of another part of the n-type waveguide core.

### CROSS-REFERENCE TO RELATED APPLICATIONS

This application is a national phase entry of PCT Application No. PCT/JP2019/045376, filed on Nov. 20, 2019, which application is hereby incorporated herein by reference.

### TECHNICAL FIELD

The present invention relates to a light reception device which is excellent in high-speed and high-sensitivity operation and a method of manufacturing the same.

### BACKGROUND

With the increase in optical communication traffic, there has been a need for a faster and smaller optical transceiver having lower power consumption and a lower cost. To achieve a smaller optical transceiver having a lower cost, an optical circuit including an optical filter or an optical modulator, which is a component, also needs to be smaller and manufactured at low cost.

Silicon photonics (SiPh) has been attracting attention in recent years as a technology for achieving small-sized optical circuits at low cost and in mass production, and research and development of SiPh optical circuits is being actively performed. However, a laser light source using Si and Ge, which are materials used mainly in SiPh, is still in a process of research and development, and no reports have been made in which the laser light source has sufficient performance. Thus, when SiPh is used for an optical transceiver, it is necessary to integrate a light source made of a compound semiconductor as a material.

As light source integration methods, a method for hybrid mounting after chipping or of mounting a laser light source chip on an SiPh optical circuit in a wafer state, a method of forming a laser after bonding an SiPh wafer and a compound semiconductor wafer through wafer bonding, and the like have been reported. In particular, because a thin-film (membrane) laser light source that can be integrated at low cost through wafer bonding can achieve a low threshold current and low-power consumption from high light confinement and carrier injection efficiency, such a laser light source is attracting attention (NPL1).

For a light reception device, for a photodiode (PD) and an avalanche photodiode (APD) that can be monolithically integrated with a thin film (membrane) laser, a lateral current injection structure illustrated in FIGS. 17A and 17B has been proposed in the related art.

The light reception device illustrated in FIG. 17A has a rectangular waveguide structure where a core 606 is i-type InGaAs having a high refractive index and cladding regions 605 and 607 are InP on an SiO₂ film 602 formed on a surface of a Si substrate. Further, InP 603 and InP 608 on both sides of the i-type InGaAs core 606 and InGaAs 604 and InGaAs 609 laminated on the InP 603 and InP 608 respectively are doped as an n-type and a p-type, respectively, to form a PIN junction. An SiO₂ protective film 610 and electrodes 611 and 612 are formed on a surface. Light is directly absorbed by the i-type InGaAs core 606 while propagating in this rectangular waveguide, and carriers are photogenerated. The i-type InGaAs core 606 may have a multiple quantum well (MQW) structure, as shown in NPL 2.

A light reception device illustrated in FIG. 17B has a rectangular waveguide structure where a core 704 is n-type InGaAsP and a cladding region 703 is InP on an SiO₂ film 702 formed on a surface of an Si substrate 701. Further, an InGaAs layer 706 is loaded on the rectangular waveguide and doped as a p type 707 and an n type 705 for each region so that a horizontal PIN junction is formed. An SiO₂ protective film 708 and electrodes 709 and 710 are formed on the surface. Some of the modes propagating through the InGaAsP 704/InP 703 optical waveguide are absorbed by the InGaAs layer 706 and the carriers are photogenerated so that the light reception device operates as a PD.

Further, the above photodiode can also be used as an APD by a strong electric field being applied. An APD is capable of highly sensitive light reception by amplifying an optical signal by an internal gain. Further, an APD is generally characterized in that a power consumption is lower than that of a semiconductor optical amplifier (SOA), which is important for a decrease in size and power consumption of an optical receiver.

Meanwhile, in recent medium- and long-distance optical communications such as Ethernet (registered trade name), a multi-value technology using pulse amplitude modulation (PAM) is often applied to secure a transmission band exceeding 400 Gbps. As a requirement for a PD and APD when a PAM technology is applied, high linearity of a response to a light input power is required.

### CITATION LIST

### Non Patent Literature

NPL1: T. Fujii et al., “Heterogeneously integrated lasers using epitaxially grown III-V active layer on directly bonded InP/SiO₂/Si substrate,” IEEE IPC 2016 (2016) 540-541.

NPL2: Y. Baumgartner, et. Al., “CMOS-Compatible Hybrid III-V/Si Photodiodes Using a Lateral Current Collection Scheme,” ECOC 2018 (2018) 1-3.

### SUMMARY

### Technical Problem

As described above, the structures of FIGS. 17A and 17B have been proposed as thin-film laser light sources and a thin-film PD and APD that can be monolithically integrated. In the structure of FIG. 17A, because the light is strongly confined in the waveguide, a large number of carriers are generated in the InGaAs core 606 at a light incidence end at the time of inputting of high-power light, and a space charge effect easily occurs. When the space charge effect occurs, an electric field inside the PIN junction is canceled out by a shielding effect of generated carriers, which causes a decrease in operating speed due to a decrease in carrier drift velocity at a certain applied voltage or a decrease in avalanche amplification gain. Further, fluctuations in the operating speed and an avalanche multiplication gain with respect to an input light power at the time of application of a constant bias voltage cause deterioration in signal quality when a PAM signal is transmitted.

In a structure illustrated in FIG. 17B, because an amount of light absorbed by the i-type InGaAs absorption layer 706 per unit length is smaller than that in FIG. 17A, the occurrence of a space charge effect can be curbed. However, in the structure of FIG. 17B, electrons and holes, which are optical carriers generated in the i-type InGaAs absorption layer 706, travel through the thin InGaAs layer to the n-type InGaAs 705 and the p-type InGaAs 707, respectively. Thus, a sheet resistance of the InGaAs layer becomes large. The large sheet resistance as a series resistance increases a CR time constant and causes a decrease in operating speed.

Further, in the structure of FIG. 17B, because light leaking from a waveguide core 704 to the i-type InGaAs absorption layer 706 also leaks to regions of the n-type InGaAs 705 and the p-type InGaAs 707 depending on dimensions of a PIN structure, carriers are photogenerated in each region. Here, holes in the n-type InGaAs 705 and electrons in the p-type InGaAs 707 are moved to the region of the i-type InGaAs 706 due to concentration diffusion of a small number of carriers, are accelerated by an electric field in the i-type InGaAs 706, and travel until the holes and the electrons reach a region of the p-type InGaAs 707 and a region of n-type InGaAs 705. In particular, the holes generated by the n-type InGaAs 705 are a factor that determines an operating speed because of their low mobility and drift velocity and long total traveling distance.

As described above, it is difficult for a lateral current injection type thin film PD or APD to achieve both curbing of a space charge effect at the time of inputting of high-power light and a high-speed and high-sensitivity operation.

An object of embodiments of the present invention is to achieve both curbing of a space charge effect at the time of inputting of high-power light and a high-speed and high-sensitivity operation in a lateral current injection type thin film (membrane) type APD.

### Means for Solving the Problem

In order to solve the problems as described above, a light reception device according to embodiments of the present invention includes, on a substrate, a first i-type cladding region; an n-type waveguide core having a predetermined width formed on the first i-type cladding region, and a second i-type cladding region in contact with a side surface of the n-type waveguide core; a p-type absorption layer, a p-type diffusion barrier layer, a p-type contact layer, and a p-type electrode formed in an upper part above a region including a part of the n-type waveguide core, with an i-type insertion layer interposed between the upper part and the region; and an n-type electrode formed on an upper surface of another part of the n-type waveguide core.

Further, a method of manufacturing a light reception device according to embodiments of the present invention includes processing n-type InGaAsP into a layer structure where a first i-type InP cladding region and the n-type InGaAsP are sequentially laminated on a substrate, to form an n-type InGaAsP waveguide core; laminating a second i-type InP cladding region and an i-type InP insertion layer to embed the n-type InGaAsP waveguide core; sequentially laminating a p-type InGaAs absorption layer, a p-type InGaAsP diffusion barrier layer, and a p-type InGaAs contact layer on the i-type InP layer; processing the p-type InGaAs absorption layer, the p-type InGaAsP diffusion barrier layer, and the p-type InGaAs contact layer in the p-type region to have a predetermined width, and removing the p-type InGaAs absorption layer, the p-type InGaAsP diffusion barrier layer, and the p-type InGaAs contact layer in the n-type region; removing a part of the i-type InP insertion layer on the n-type InGaAsP waveguide core in the n-type region; and forming electrodes on a surface of the p-type InGaAs contact layer and a surface of the n-type InGaAsP waveguide core.

### Effects of Embodiments of the Invention

According to embodiments of the present invention, effects that it is possible to achieve both curbing of a space charge effect at the time of inputting of high-power light and a high-speed and high-sensitivity operation, and to apply embodiments of the present invention to large-capacity communication using a multi-valued technology such as a PAM signal can be obtained by adopting a thin film APD structure to which a vertical UTC-PD structure has been applied.

### BRIEF DESCRIPTION OF THE DRAWINGS

FIG. 1 is a top view of a light reception device according to a first embodiment of the present invention.

FIG. 2A is a cross-sectional view taken along line A-A′ of the light reception device according to the first embodiment of the present invention.

FIG. 2B is a cross-sectional view taken along line B-B′ of the light reception device according to the first embodiment of the present invention.

FIG. 3 is a diagram illustrating a finite difference time domain method (FDTD) simulation calculation result in a guided light mode in the light reception device according to the first embodiment of the present invention.

FIG. 4A is a diagram illustrating an energy diagram when a reverse bias of 4 V is applied in a p-type region of the light reception device according to the first embodiment of the present invention.

FIG. 4B is a diagram illustrating an electric field distribution when a reverse bias of 4 V is applied in the p-type region of the light reception device according to the first embodiment of the present invention.

FIG. 5 is a diagram illustrating dependence of an avalanche breakdown voltage and an electric field on an impurity concentration.

FIG. 6 is a diagram illustrating dependence of a 3 dB band of a photoelectric response and a light reception sensitivity on a length of the p-type region.

FIG. 7 is a diagram illustrating a wafer bonding process in a method of manufacturing a light reception device according to the first embodiment of the present invention.

FIG. 8 is a diagram illustrating a process of removing an InP substrate in the method of manufacturing the light reception device according to the first embodiment of the present invention.

FIG. 9 is a diagram illustrating a process of forming an n-type InGaAsP waveguide core in the method of manufacturing the light reception device according to the first embodiment of the present invention.

FIG. 10 is a diagram illustrating a crystal regrowth process in the method of manufacturing the light reception device according to the first embodiment of the present invention.

FIG. 11 is a diagram illustrating an etching process in a p-type region in the method of manufacturing the light reception device according to the first embodiment of the present invention.

FIG. 11B is a diagram illustrating an etching process in an n-type region in the method of manufacturing the light reception device according to the first embodiment of the present invention.

FIG. 12A is a diagram illustrating a process of forming a p-type ohmic electrode in the p-type region in the method of manufacturing the light reception device according to the first embodiment of the present invention.

FIG. 12B is a diagram illustrating a process of forming an n-type ohmic electrode in the n-type region in the method of manufacturing the light reception device according to the first embodiment of the present invention.

FIG. 13A is a diagram illustrating a process of depositing an SiO₂ film in the p-type region in the method of manufacturing the light reception device according to the first embodiment of the present invention.

FIG. 13B is a diagram illustrating a process of depositing an SiO₂ film in the n-type region in the method of manufacturing the light reception device according to the first embodiment of the present invention.

FIG. 14A is a diagram illustrating a process of forming an electrode opening in the p-type region in the method of manufacturing the light reception device according to the first embodiment of the present invention.

FIG. 14B is a diagram illustrating a process of forming an electrode opening in the n-type region in the method of manufacturing the light reception device according to the first embodiment of the present invention.

FIG. 15A is a diagram illustrating a process of vapor-depositing an electrode material in the p-type region in the method of manufacturing the light reception device according to the first embodiment of the present invention.

FIG. 15B is a diagram illustrating a process of vapor-depositing an electrode material in the n-type region in the method of manufacturing the light reception device according to the first embodiment of the present invention.

FIG. 16 is a top view of a light reception device according to a second embodiment of the present invention.

FIG. 17A is a cross-sectional view of a light reception device in the related art.

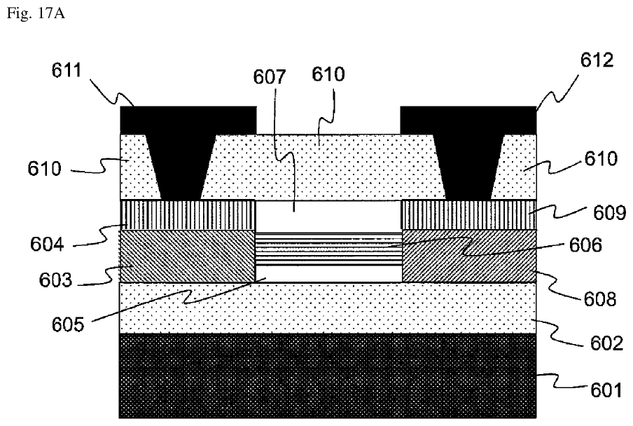

FIG. 17B is a cross-sectional view of the light reception device in the related art.

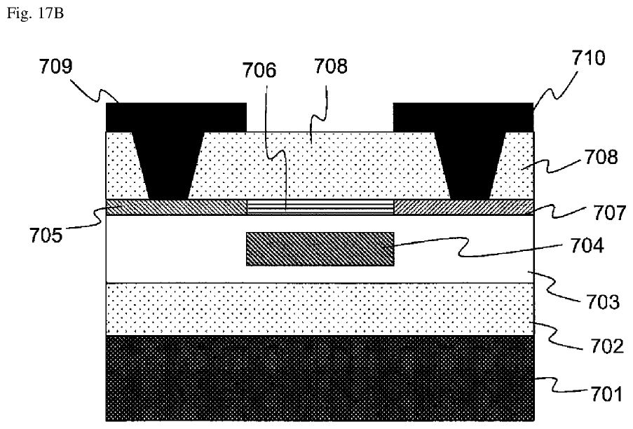

### DETAILED DESCRIPTION OF ILLUSTRATIVE EMBODIMENTS

### First Embodiment

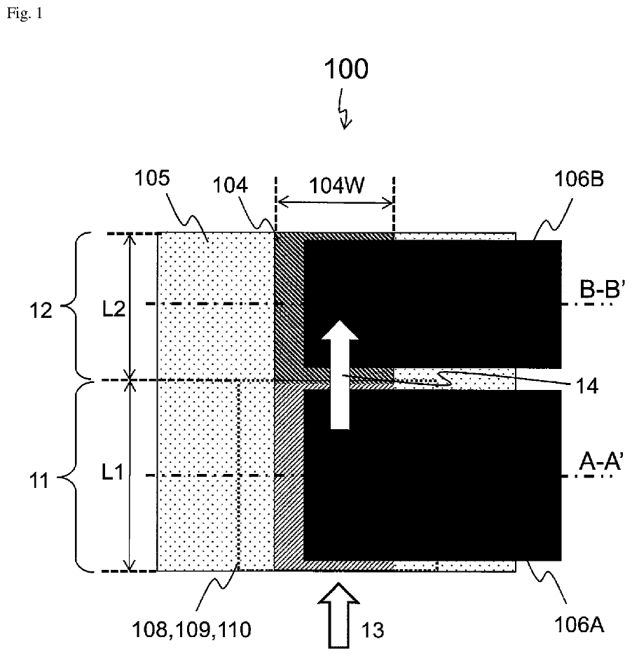

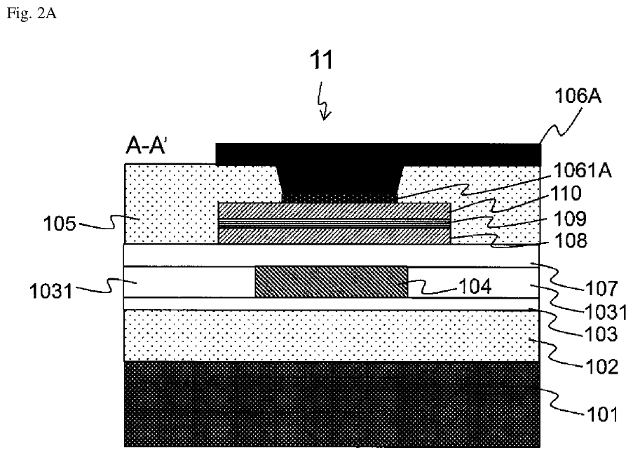

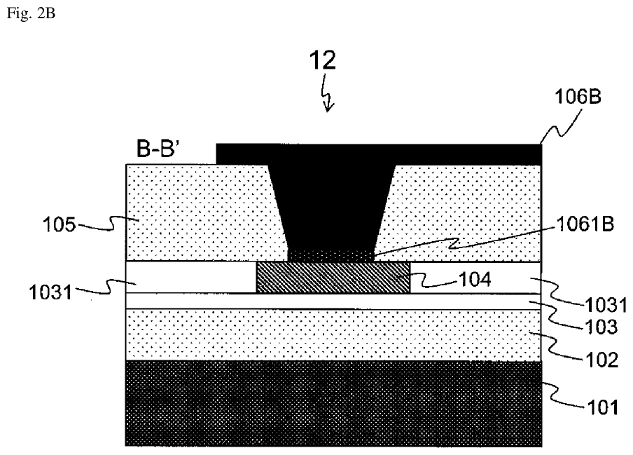

Hereinafter, a light reception device according to the first embodiment of the present invention will be described with reference to FIGS. 1 to 2B.

### Configuration of Light Reception Device

FIG. 1 illustrates a top view of a light reception device 100 according to the first embodiment of the present invention, and FIGS. 2A and 2B show a cross-sectional view of the light reception device 100 according to the first embodiment of the present invention. FIG. 2A is a cross-sectional view taken along line A-A′ in FIG. 1, and FIG. 2B is a cross-sectional view taken along line B-B′ in FIG. 1.

As illustrated in FIG. 1, the light reception device 100 includes a p-type region 11 having a p-type electrode 106A and an n-type region 12 having an n-type electrode 106B.

As illustrated in FIG. 2A, the p-type region 11 of the light reception device 100 includes an Si substrate 101, a dielectric insulating film (SiO₂) 102, an n-type InGaAsP waveguide core (energy gap composition: 0.95 eV) 104, a first i-type InP cladding region 103, a second i-type InP cladding region 1031, an i-type InP insertion layer 107, a p-type InGaAs absorption layer 108, a p-type InGaAsP diffusion barrier layer (energy gap composition: 0.9 eV) 109, a p-type InGaAs contact layer 110, an embedded insulating film (SiO₂) 105, a p-type ohmic electrode 1061A, and a p-type electrode 106A. Here, the second i-type InP cladding region 1031 is in contact with a side surface of the n-type InGaAsP waveguide core 104.

Further, in the p-type region 11, the p-type InGaAs absorption layer 108, a p-type InGaAsP diffusion barrier layer 109, and the p-type InGaAs contact layer 110 may be laminated via the i-type InP insertion layer 107 above a region including all parts of the n-type InGaAsP waveguide core 104 or may be laminated via the i-type InP insertion layer 107 above a region including a part of the n-type InGaAsP waveguide core 104.

Further, in the p-type region 11, the p-type ohmic electrode 1061A may be formed on an upper surface of a region including all parts of the p-type InGaAs contact layer 110 or may be formed on an upper surface of a region including a part of the p-type InGaAs contact layer 110.

Further, in the p-type region 11, the p-type electrode 106A may be formed on an upper surface of a region including all parts of the p-type ohmic electrode 1061A or may be formed on an upper surface of a region including a part of the p-type ohmic electrode 1061A.

As illustrated in FIG. 2B, the n-type region 12 of the light reception device 100 includes the Si substrate 101, the dielectric insulating film (SiO₂) 102, the n-type InGaAsP waveguide core (energy gap composition: 0.95 eV) 104, the first i-type InP cladding region 103, the second i-type InP cladding region 1031, the embedded insulating film (SiO₂) 105, the n-type ohmic electrode 1061B, and the n-type electrode 106B.

Here, in the n-type region 12, the n-type ohmic electrode 1061B may be formed on an upper surface of the region including all parts of the n-type InGaAsP waveguide core 104 or may be formed on an upper surface of the region including a part of the n-type InGaAsP waveguide core 104.

Here, in the n-type region 12, the n-type electrode 106B may be formed on an upper surface of a region including all parts of the n-type ohmic electrode 1061B or may be formed on an upper surface of a region including a part of the n-type ohmic electrode 1061B.

As described above, the light reception device loo has a configuration of providing the p-type InGaAs absorption layer 108, the p-type InGaAsP diffusion barrier layer 109, the p-type InGaAs contact layer 110, the p-type ohmic electrode 1061A, and the p-type electrode 106A above a part of the n-type waveguide core 104 included in the p-type region 11 via the i-type InP insertion layer 107, and includes the n-type ohmic electrode 1061B and the n-type electrode 106B on an upper surface of another part of the n-type waveguide core 104 included in the n-type region 12.

Here, a length L1 of the p-type region 11 preferably ranges from 1 μm to 30 μm, and a length L2 of the n-type region 12 preferably ranges from 1 μm to 10 μm. Further, a width Wi of the n-type InGaAsP waveguide core 104 preferably ranges from 400 nm to 800 nm.

Further, contact with the p-type semiconductor is made via the p-type InGaAs contact layer 110 in the p-type region 11. On the other hand, contact with the n-type semiconductor is performed via the n-type InGaAsP waveguide core 104 in the n-type region 12.

In the above structure, a vertical PIN junction is formed, and the p-type InGaAs absorption layer 108 absorbs light in a communication wavelength band, unlike the related art, so that the structure operates as a PD. A composition of p-type InGaAs is lattice-matched with InP.

A composition of the p-type InGaAsP diffusion barrier layer 109 may be a composition that is lattice-matched with InP and of which a bandgap energy is larger than that of the p-type InGaAs and preferably ranges from 0.85 eV to 0.9 eV.

While an energy gap composition of the n-type InGaAsP waveguide core 104 is 0.95 eV, the composition may be a composition that is lattice-matched with InP and does not absorb input light (light having a wavelength of 1.55 μm in the present embodiment) and preferably ranges from 0.81 eV to 0.95 eV.

The p-type InGaAs contact layer 110 is subjected to high-concentration doping of about 1×1019 cm-3 in order to make ohmic contact with the p-type ohmic electrode 1061A. Similarly, the n-type InGaAsP waveguide core 104 is subjected to high-concentration doping of about 1×1019 cm-3 in order to make ohmic contact with the n-type ohmic electrode 1061B. Here, a doping concentration is not limited to about 1×1019 cm-3 and may be as high as about 1×1018 cm-3 to 1×1021 cm-3.

### Operating Principle of Light Reception Device

Next, an operating principle of the light reception device 100 according to the first embodiment of the present invention will be described with reference to FIGS. 2A and 2B.

The p-type region 11 and the n-type region 12 in the light reception device boo include a common n-type InGaAsP waveguide core 104 on the common Si substrate 101. Light is input as an optical signal from an end face of the n-type InGaAsP waveguide core 104 in the p-type region 11 (a light input direction is indicated by an arrow 13 in FIG. 1), propagates through the n-type InGaAsP waveguide core 104 (a waveguide direction of the light is indicated by an arrow 14 in FIG. 1), and is converted into electrons and holes in the p-type region 11, and the electrons travel through the n-type InGaAsP waveguide core 104 from the p-type region 11 to the n-type region 12 and are output as an electrical signal from the n-type electrode 106B. As described above, the p-type region 11 and the n-type region 12 are adjacent to each other in the waveguide direction of the light.

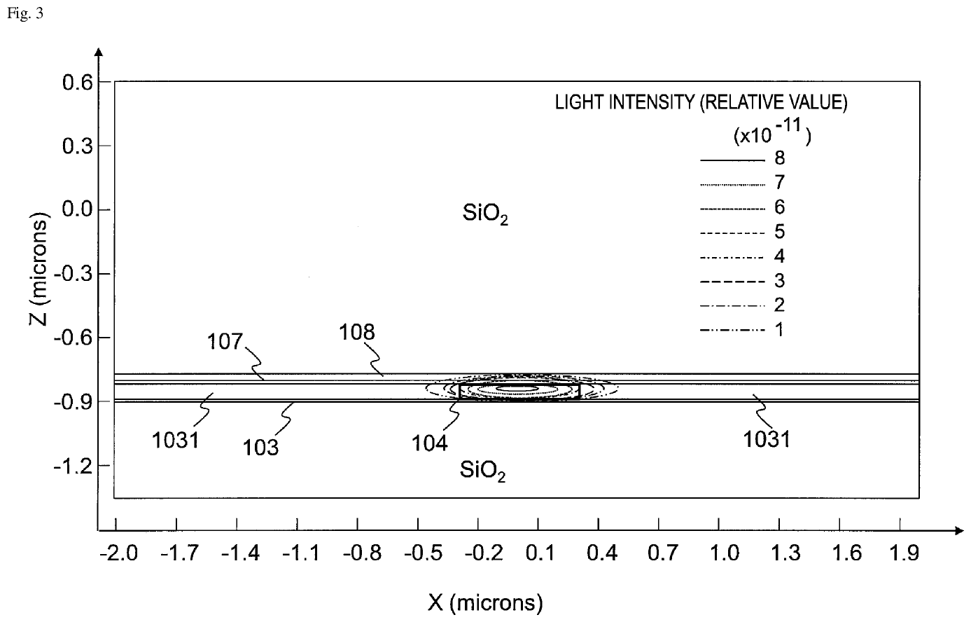

The light reception device 100 functions as a PD for light in a communication wavelength band. In a PD region (p-type region 11) illustrated in FIGS. 2A and 3, a part of the light propagating through the n-type InGaAsP waveguide core 104 is absorbed by the p-type InGaAs absorption layer 108 loaded above the n-type InGaAsP waveguide core 104, and electron-hole pairs are generated.

FIG. 3 illustrates a finite-difference time domain method (FDTD) simulation calculation result in a mode of guided light (wavelength: 1.55 μm) when a width of the n-type InGaAsP waveguide core 104 is 600 nm, a thickness thereof is 100 nm, a thickness of the first i-type InP cladding region 103 is 50 nm, a thickness of the second i-type InP cladding region 1031 is 100 nm, a thickness of the i-type InP insertion layer 107 is 50 nm, and a thickness of the p-type InGaAs absorption layer 108 is 50 nm.

In FIG. 3, relative values (1×10-11 to 8×10-11) of light intensity are indicated by elliptical solid lines, dotted lines, and dashed lines. Spreading of these ellipses indicates a state in which light guided in the n-type InGaAsP waveguide core 104 is leaking.

As illustrated in FIG. 3, it can be seen that the guided light in the n-type InGaAsP waveguide core 104 leaks to the p-type InGaAs absorption layer 108. In this case, when an integrated value of all the guided light is Po and an integrated value of the guided light leaking to the p-type InGaAs absorption layer 108 is PA, a value of PA/Po is 8%. Here, the value of PA/Po can be adjusted according to the design such as the width of the n-type InGaAsP waveguide core 104 and the thickness of the i-type InP insertion layer 107 and preferably ranges from 2% to 10%.

As described above, the light leaked to the p-type InGaAs absorption layer 108 is absorbed by the p-type InGaAs absorption layer 108 and electron-hole pairs are generated. The electrons generated in the p-type InGaAs absorption layer 108 flow into the i-type InP insertion layer 107, are accelerated, and travel to the n-type InGaAsP waveguide core 104 by a diffusion process and an electric field. Here, the p-type InGaAsP diffusion barrier layer 109 serves to prevent the photogenerated electrons from diffusing toward the p-type InGaAs contact layer 110. Here, an electric field is applied between the p-type electrode 106A and the n-type electrode 106B.

On the other hand, because the holes generated in the p-type InGaAs absorption layer 108 are a large number of carriers, the holes are immediately dielectrically relaxed. Here, a Uni-traveling carrier photodiode (UTC-PD, NPL3: T. Ishibashi, N. Shimizu, S. Kodama, H. Ito, T. Nagatsuma, and T. Furuta, “Uni-Traveling-Carrier Photodiodes”, in Ultrafast Electronics and Optoelectronics, M. Nuss and J. Bowers, eds., Vol. 13 of OSA Trends in Optics and Photonics Series (Optical Society of America, 1997), paper UC3) structure is formed vertically. In a UTC-PD, because photogenerated electrons flow perpendicular to a laminating direction of the InGaAs absorption layer, a sheet resistance of the InGaAs absorption layer can be substantially ignored, and it is possible to prevent a decrease in operating speed caused by the increase in a CR time constant. In this UTC-PD structure, only electrons contribute to a carrier traveling time, and holes do not contribute. Further, because an electron speed overshoot phenomenon can be used, the carrier traveling time can be greatly shortened as compared with the lateral current injection type PIN or PD of the related art.

Further, because the photogenerated holes are immediately dielectrically relaxed, a shielding effect of an internal electric field (space charge effect) due to photogenerated electron-hole pairs does not occur. Thus, because the space charge effect at the time of inputting of high-power light can be curbed, fluctuation of an operating speed at the time of application of a constant bias voltage can be curbed and it is possible to achieve both a high-speed operation and a high-sensitivity operation.

Further, an electric field is concentrated on the i-type InP insertion layer 107. This layer is made as an ultrathin layer ranging from 50 nm to 100 nm so that the layer functions as an avalanche multiplication layer in which electrons and holes are rapidly accelerated and impact ionization is caused.

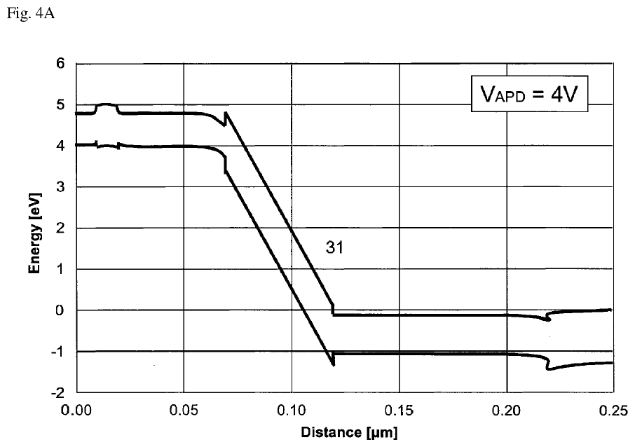

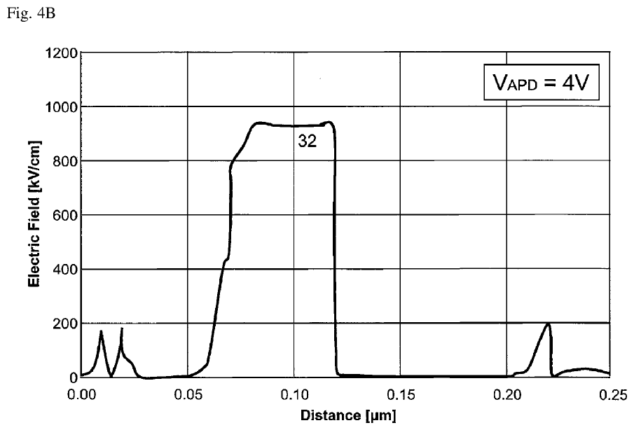

FIGS. 4A and 4B illustrate an energy diagram (FIG. 4A) and an electric field distribution (FIG. 4B) when a reverse bias of 4 V is applied in the p-type region 11 of the light reception device 100 according to the first embodiment of the present invention. A horizontal axis in each figure indicates a distance from the p-type InGaAs contact layer 110 to the substrate 101. For film thicknesses and impurity concentrations of the respective layers, the film thickness and the impurity concentration of the p-type InGaAs contact layer 110 were 10 nm and 1×1019 cm-3, the film thickness and the impurity concentration of the p-type InGaAsP diffusion barrier layer 109 were 10 nm and 1×1019 cm-3, the film thickness and the impurity concentration of the p-type InGaAs absorption layer were 50 nm and 1×1019 cm-3, the film thickness and the impurity concentration of an i-type InP avalanche multiplication layer were 50 nm and 1×1015 cm-3, and the film thickness and the impurity concentration of the n-type InGaAsP waveguide core were 100 nm and 1×1019 cm-3, and a Poisson equation and a current continuity equation were combined for calculation. It can be seen from FIG. 4B that a strong electric field of about 1 MeV/cm is applied to the i-type InP insertion layer 107.

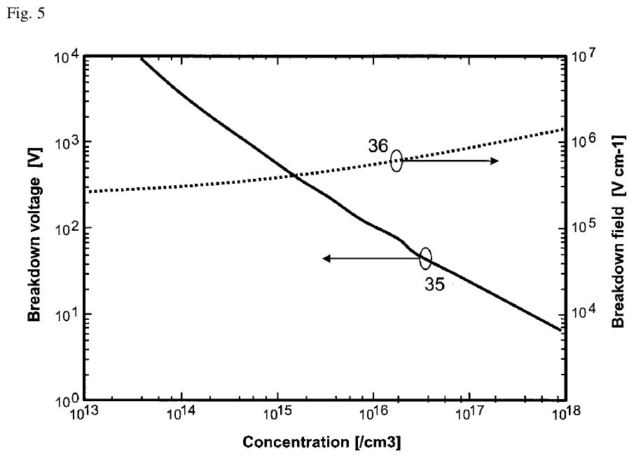

FIG. 5 illustrates dependence of an avalanche breakdown voltage 35 and an electric field 36 on an impurity concentration shown in NPL 4 (Kyuregyan, A. S. and S. N. Yurkov, Sov. Phys. Semicond. 23, 10 (1989) 1126-1132.

Http://www.ioffe.ru/SVA/NSM/Semicond/InP/electric.html). It can be seen that an avalanche breakdown electric field is about 1 MeV/cm at about 1016/cm3 corresponding to an impurity concentration of i-type InP, and avalanche multiplication occurs. Considering a result of FIG. 4, in the p-type region 11 of the light reception device 100 according to the first embodiment of the present invention, because a high electric field of about 1 MeV/cm is applied at the time of application of a reverse bias of 4 V, the avalanche multiplication occurs and an APD operation is possible.

In this avalanche multiplication, in the light reception device according to the embodiment, because the space charge effect at the time of inputting of high-power light can be curbed as described above, fluctuation of an internal electric field with respect to light input power can be curbed and the avalanche multiplication gain can be prevented from fluctuating.

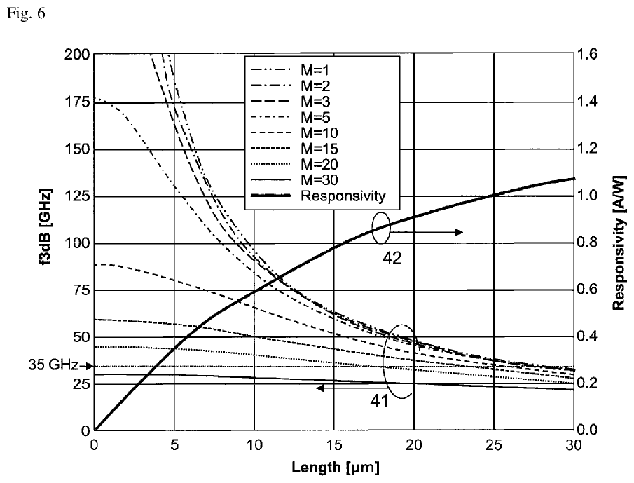

FIG. 6 is a diagram illustrating results of calculating a dependence of a 3 dB band of a photoelectric response on a PD length and a dependence of a light reception sensitivity on a PD length when a light absorption coefficient of the p-type InGaAs absorption layer is α=8000 cm-1, an electron drift speed ve=1×105 cm/s, an amount of light leakage from the n-type InGaAsP waveguide core to the p-type InGaAs absorption layer is 8%, a width of the p-type InGaAs absorption layer is 1 μm, and a wavelength thereof is 1550 nm. Further, a result of calculation with the avalanche multiplier M as a parameter is plotted for the 3 dB band of the photoelectric response. The calculation was performed by using impedance calculated based on a Poisson equation and a current continuity equation. It can be seen that at a reception sensitivity exceeding 0.8 A/W (that is, a PD length is 15 μm or more), a 3 dB band exceeding 35 GHz can be achieved at a magnification M ranging from 1 to 20.

As described above, the light reception device according to the first embodiment adopts a thin film APD structure to which a vertical UTC-PD structure has been applied, making it possible to maintain integration with a thin film LD and substantially ignore a sheet resistance of the InGaAs absorption layer as in the lateral current injection type PD or APD, and to prevent an operating speed from decreasing due to an increase in the CR time constant. Further, it is possible to shorten a traveling time of the carriers. Further, through curbing of the space charge effect, it is possible to prevent fluctuations in the operating speed and the avalanche multiplication gain when a constant bias voltage is applied.

Thus, the light reception device according to the first embodiment can stably provide a high-speed and high-sensitivity operation.

### Method of Manufacturing Light Reception Device

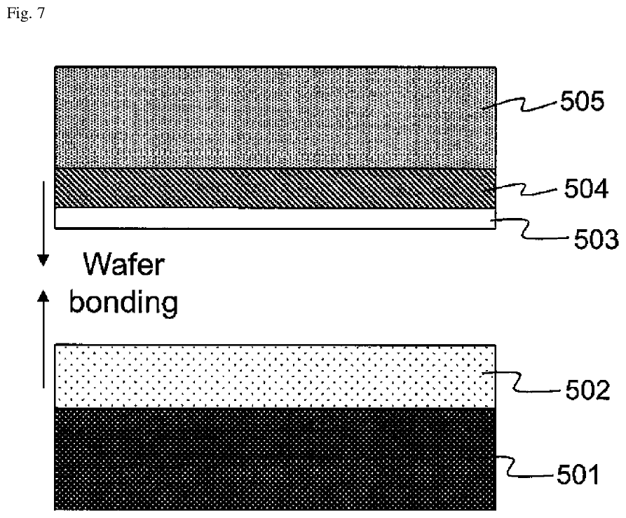

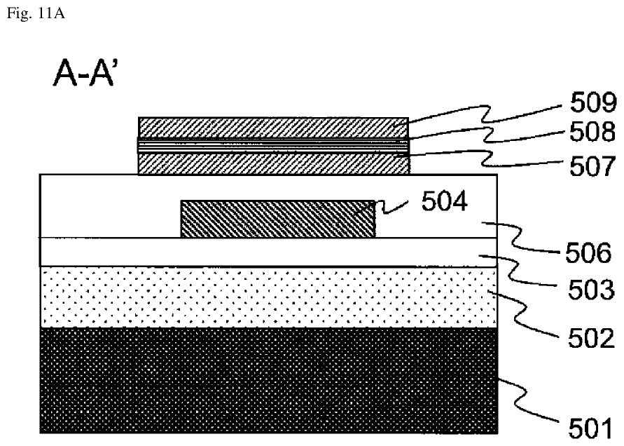

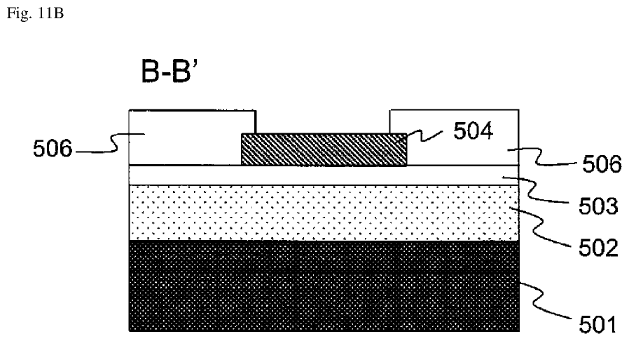

Next, a method of manufacturing the light reception device 100 in the present embodiment will be described with reference to FIGS. 7 to 15B. FIGS. 7 to 10 illustrate a common manufacturing process in the p-type region 11 and the n-type region 12. FIGS. 11A, 12A, 13A, 14A, and 15A illustrate the manufacturing process in the p-type region 11 and illustrate an A-A′ cross section in the p-type region 11 illustrated in FIG. 2A. FIGS. 11B, 12B, 13B, 14B, and 15B illustrate the manufacturing process in the n-type region 12 and illustrate a B-B′ cross section in the n-type region 12 illustrated in FIG. 2B.

First, an n-type InGaAsP layer 504 and a first i-type InP cladding region 503 are crystal-grown on the InP substrate 505 by using a known epitaxial crystal growth technology. Subsequently, by using a wafer bonding technology, a crystal on the InP substrate having the first i-type InP cladding region 503 on a lower surface and an Si substrate 501 having a thermal oxide film 502 on an upper surface are wafer-bonded with a surface of the first i-type InP cladding region 503 and a surface of the thermal oxide film 502 being aligned. The Si substrate may be, for example, an SOI substrate in which an SiPh optical circuit such as an Si waveguide has been formed (FIG. 7).

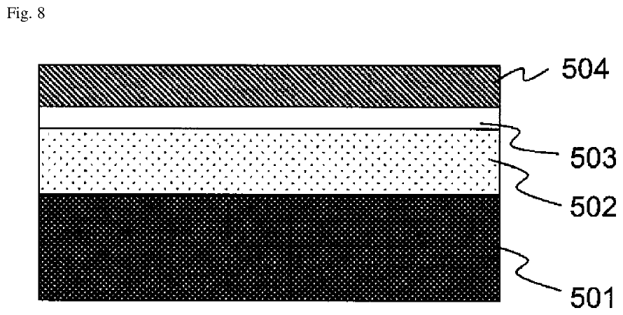

Thereafter, the InP substrate 505 is removed by using a known substrate polishing technology and wet etching technology (FIG. 8).

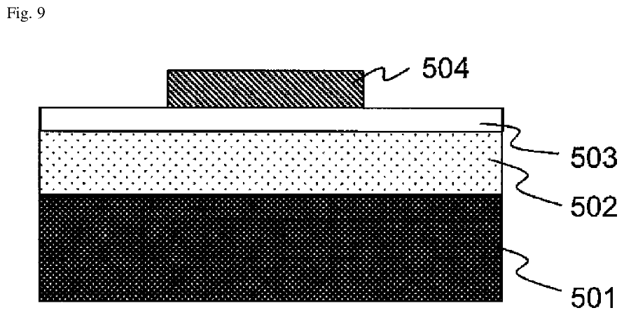

Then, the n-type InGaAsP layer 504 is etched by using a known photolithography and dry etching technology and processed so that the n-type InGaAsP waveguide core 504 is formed (FIG. 9). In this case, it is also possible to form a tapered waveguide that simultaneously performs spot size conversion.

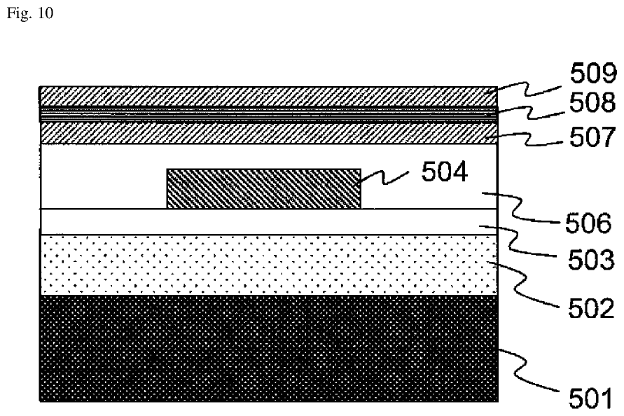

Then, crystal re-growth of an i-type InP layer 506 in which the n-type InGaAsP waveguide core 504 is embedded (corresponding to the second i-type InP cladding region 1031 and the i-type InP insertion layer 107 in FIGS. 2A and 2B), the p-type InGaAs absorption layer 507, the p-type InGaAsP diffusion barrier layer 508, and the p-type InGaAs contact layer 509 is performed by using a known crystal growth technology (FIG. 10). Here, doping of impurities in the n-type InGaAsP waveguide core 504, the p-type InGaAs absorption layer 507, the p-type InGaAsP diffusion barrier layer 508, and the p-type InGaAs contact layer 509 is all performed at the time of crystal growth.

Subsequently, in the p-type region 11, the p-type InGaAs absorption layer 507, the p-type InGaAsP diffusion barrier layer 508, and the p-type InGaAs contact layer 509 are etched to have a desired width (600 nm in the present embodiment) (FIG. 11A).

Simultaneously, the p-type InGaAs absorption layer 507, the p-type InGaAsP diffusion barrier layer 508, and the p-type InGaAs contact layer 509 in the n-type region 12 are all etched and removed. Subsequently, a part of the i-type InP layer 506 on the n-type InGaAsP waveguide core 504 is removed by dry etching (FIG. 11B).

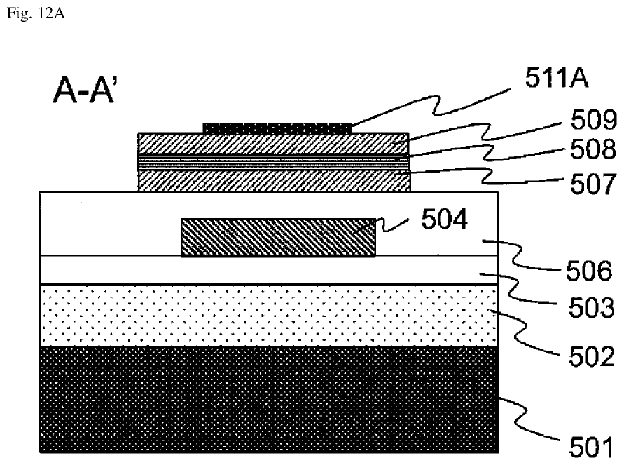

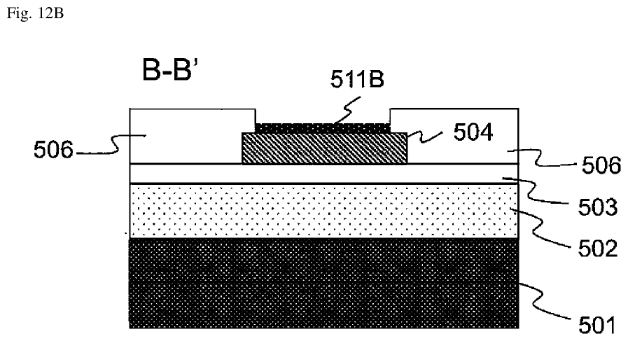

Then, in the p-type region 11, a p-type ohmic electrode 511A is formed on the p-type InGaAs contact layer 509 (FIG. 12A). In the n-type region 12, an n-type ohmic electrode 511B is formed on the n-type InGaAsP waveguide core 504 (FIG. 12B). Here, although the n-type ohmic electrode 511B is formed only on the n-type InGaAsP waveguide core 504, the n-type ohmic electrode 511B may be formed in a region including a part of the i-type InP layer 506 and the n-type ohmic electrode 511B merely need to be formed on a part of the n-type InGaAsP waveguide core 504. Thin titanium (thickness: 50 nm), platinum (thickness: 80 nm), and gold (thickness: 100 nm) are used as ohmic electrode materials.

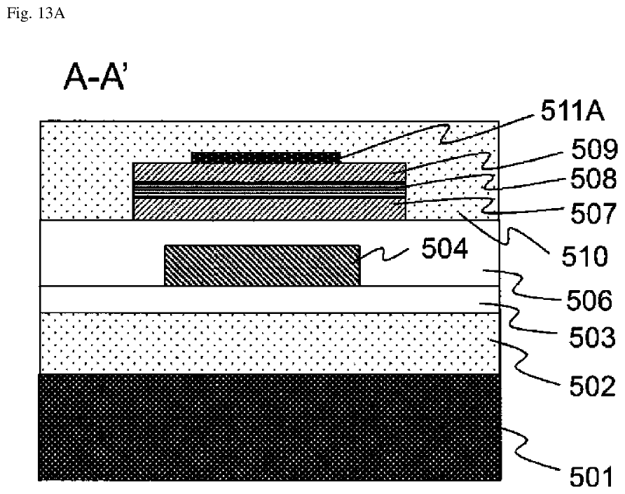

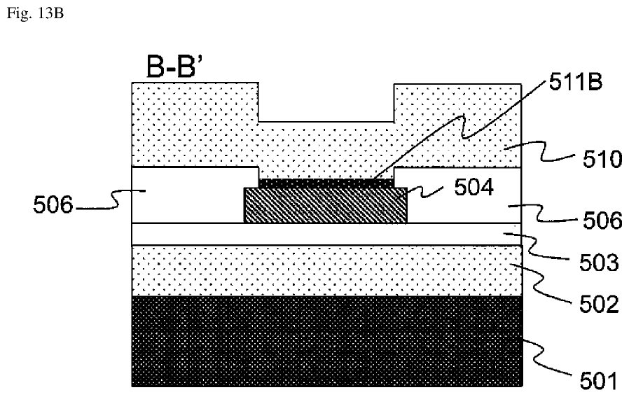

Then, an SiO₂ film 510 for surface protection is deposited by using a sputtering technology in order to form electrodes 512A and 512B on a surface of the p-type ohmic electrode 511A and a surface of the n-type ohmic electrode 511B, respectively (FIGS. 13A and 13B).

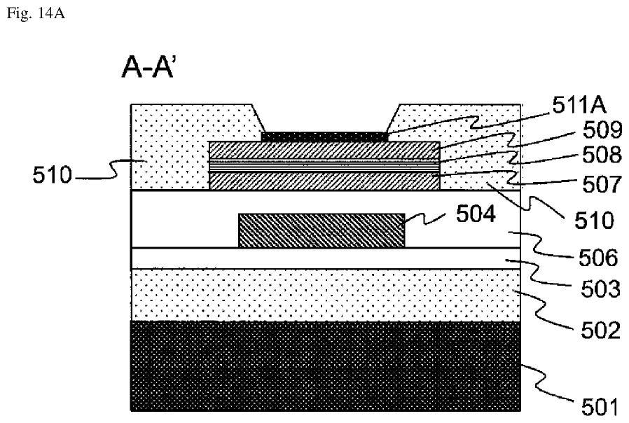

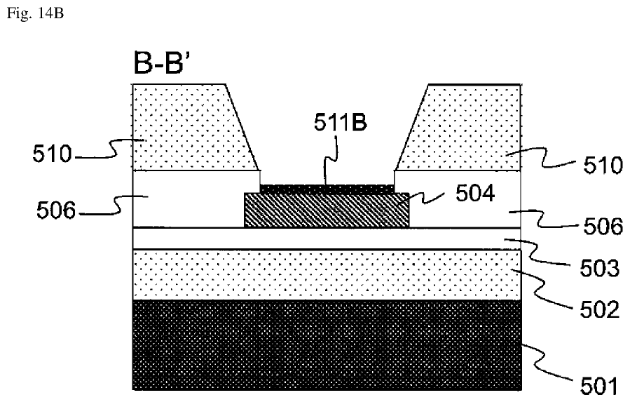

Next, for electrode formation, an opening is provided in a part of the surface protection SR), film 510 by dry etching (FIGS. 14A and 14B).

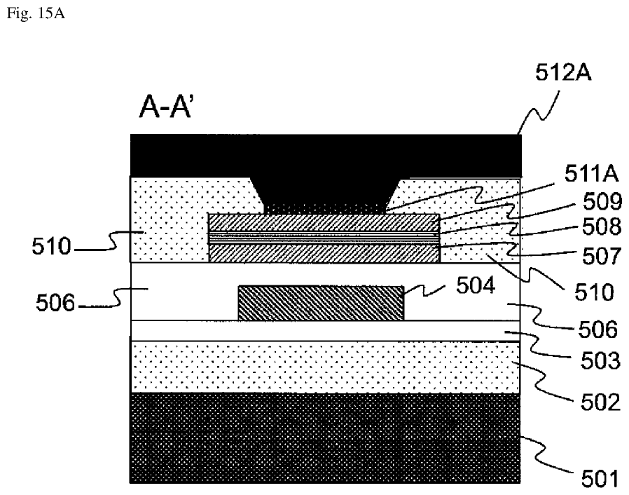

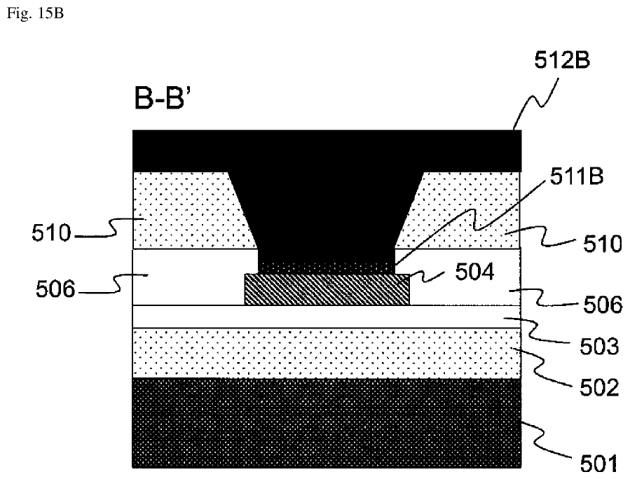

Finally, an electrode material is vapor-deposited by using a known vacuum deposition technology so that the electrodes 512A and 512B are formed (FIGS. 15A and 15B). A thick layer of gold (thickness: about 2 μm) was used as the electrode material. Thus, the light reception device 100 illustrated in FIGS. 1 to 2B is manufactured.

Further, for formation of the p-type ohmic electrode 511A and the n-type ohmic electrode 511B, the steps illustrated in FIGS. 12A and 12B are omitted, and the p-type ohmic electrode 511A and the n-type ohmic electrode 511B may be formed before electrode metals illustrated in FIGS. 15A and 15B are vapor-deposited in the step of forming the electrodes 512A and 512B.

### Second Embodiment

Next, a light reception device according to a second embodiment of the present invention will be described.

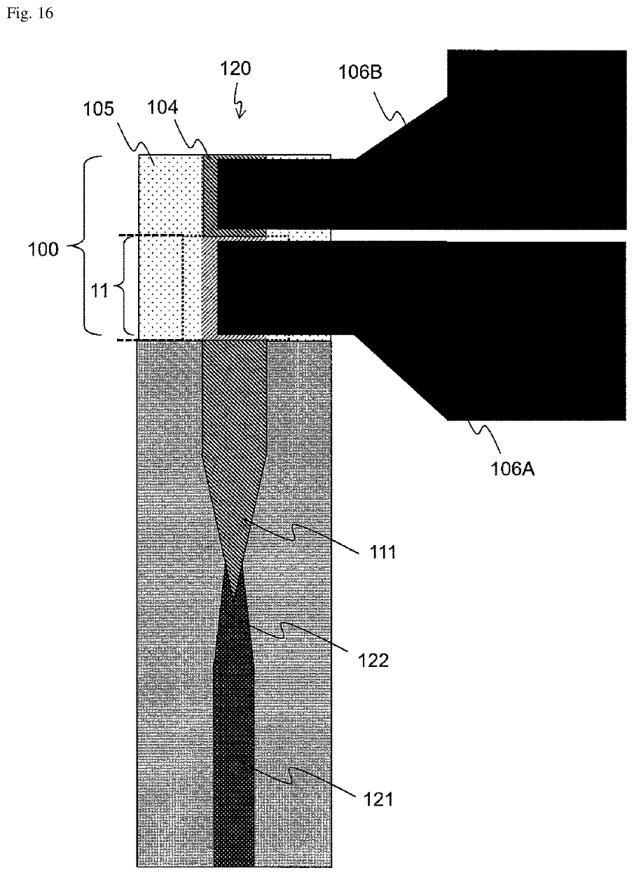

FIG. 16 illustrates a top view of a light reception device 120 according to the second embodiment of the present invention. An Si photonics device in which an InGaAsP tapered waveguide 111 is included at an end portion of the p-type region 11 of the light reception device 100, and an Si tapered waveguide 122 of an optical waveguide 121 formed on the Si substrate is integrated at a distal end portion of the InGaAsP tapered waveguide 111 is shown.

Light is introduced from the optical waveguide 121 formed on the Si substrate. The introduced light is subjected to spot size conversion by the Si tapered waveguide 122 and the InGaAsP tapered waveguide in and propagates toward the light reception device 100 while being confined in the n-type InGaAsP waveguide core 104.

Light propagating through the n-type InGaAsP waveguide core 104 and being incident on the light reception device 100 is output to the n-type electrode 106B as an electric signal according to an operation of the light reception device 100 shown in the second embodiment of the present invention.

Thus, the light reception device 120 according to the embodiment can prevent fluctuations in the operating speed and the avalanche multiplication gain when a constant bias voltage is applied, through curbing of the space charge effect, and prevent a decrease in operating speed due to an increase in the CR time constant.

The light reception device 120 according to the second embodiment of the present invention can be manufactured using the same manufacturing method as that for the light reception device according to the first embodiment, and when the n-type InGaAsP waveguide core 504 in the processes illustrated in FIGS. 9A and 9B is processed so that the n-type InGaAsP layer 504 is formed, it is possible to form the InGaAsP tapered waveguide in that simultaneously performs spot size conversion. Further, for integration of the InGaAsP tapered waveguide in and the Si tapered waveguide 122, a known hybrid integration or monolithic integration may be used.

The light reception device 100 according to the first embodiment of the present invention and the light reception device 120 according to the second embodiment of the present invention can be integrated with a thin film (membrane) type laser light source (for example, NPL1).

In the embodiment of the present invention, although Si is used for the substrate and an oxide film (SiO₂) is formed on Si, InP may be used for the substrate. In a manufacturing method when InP is used for the substrate, the Si substrate 501 and the thermal oxide film 502 are replaced with InP in the description of the manufacturing method described above and the steps illustrated in FIGS. 8A and 8B are started. For the substrate, another semiconductor substrate such as an SOI substrate or a GaAs substrate, a sapphire substrate, or the like can also be used.

In the embodiments of the present invention, although SiO₂by thermal oxidation is used as the dielectric insulating film, SiO₂by a plasma CVD method or the like may be used. Further, a silicon nitride (SiNx) may be used instead of SiO₂.

In the embodiments of the present invention, a wavelength of input light is 1.55 μm, but it is possible to support a wavelength in another long wavelength band such as 1.3 μm. In that case, a composition of InGaAsP used for the n-type InGaAsP waveguide core needs to be a composition that does not absorb the input light.

In the embodiments of the present invention, it is possible to support not only light having wavelengths in a long wavelength band, but also light having other wavelengths by using not only an InP-based compound crystal, but also other materials such as a GaAs-based compound crystal and a nitride-based compound crystal.

Although dimensions of components, parts, and the like of the light reception device and the method of manufacturing the light reception device according to the first embodiment or the second embodiment of the present invention have been described, the dimensions are not limited thereto and may be dimensions allowing each component, part, and the like to function.

### INDUSTRIAL APPLICABILITY

The embodiments of present invention relates to a light reception device excellent in a high-speed and high-sensitivity operation, and can be applied to, for example, optical communication devices and systems using an optical semiconductor device.

### Reference Signs List

100 Light reception device
101 Si substrate
103 First i-type InP cladding region
1031 Second i-type InP cladding region
104 n-type InGaAsP waveguide core
107 i-type InP insertion layer
108 p-type absorption layer
109 p-type diffusion barrier layer
110 p-type contact layer
106A p-type electrode
106B n-type electrode
1061A p-type ohmic electrode
1061B n-type ohmic electrode

1-6. (canceled)

7. A light reception device comprising:
a first i-type cladding region on a substrate;
an n-type waveguide core on the substrate, the n-type waveguide core having a predetermined width and a second i- type cladding region in contact with a side surface of the n-type waveguide core on the first i-type cladding region;
a p-type absorption layer, a p-type diffusion barrier layer, a p-type contact layer, and a p-type electrode in an upper part of the substrate above a region including a part of the n-type waveguide core, with an i-type insertion layer interposed between the upper part and the region; and
an n-type electrode on an upper surface of another part of the n-type waveguide core.

8. The light reception device according to claim 7, wherein
a thickness of the i-type insertion layer ranges from 50 nm to 100 nm.

9. The light reception device according to claim 7, wherein
the first i-type cladding region and the second i-type cladding region are i-type InP,
the n-type waveguide core is n-type InGaAsP that is lattice-matched to InP and has a composition in which light guided through the n-type waveguide core is not absorbed,
the i-type insertion layer is i-type InP,
the p-type absorption layer is p-type InGaAs lattice-matched to InP,
the p-type contact layer is p-type InGaAs lattice-matched to InP, and
the p-type diffusion barrier layer is p-type InGaAsP that is lattice-matched to InP.

10. The light reception device according to claim 9, wherein
the InGaAsP of the p-type diffusion barrier layer has a bandgap ranging from 0.85 eV to 0.9 eV.

11. The light reception device according to claim 9, wherein
the InGaAsP of the n-type waveguide core has an energy gap ranging from 0.81 eV to 0.95 eV.

12. A method of manufacturing a light reception device, the method comprising:
processing n-type InGaAsP in a layer structure where a first i-type InP cladding region and the n-type InGaAsP are sequentially laminated on a substrate, to form an n-type InGaAsP waveguide core;
laminating a second i-type InP cladding region and an i-type InP insertion layer to embed the n-type InGaAsP waveguide core;
sequentially laminating a p-type InGaAs absorption layer, a p-type InGaAsP diffusion barrier layer, and a p-type InGaAs contact layer on the i-type InP layer;
processing the p-type InGaAs absorption layer, the p-type InGaAsP diffusion barrier layer, and the p-type InGaAs contact layer in a p-type region to have a predetermined width, and removing the p-type InGaAs absorption layer, the p-type InGaAsP diffusion barrier layer, and the p-type InGaAs contact layer in an n-type region;
removing a part of the i-type InP insertion layer on the n-type InGaAsP waveguide core in the n-type region; and
forming respective electrodes on a surface of the p-type InGaAs contact layer and a surface of the n-type InGaAsP waveguide core.

13. The method of manufacturing a light reception device according to claim 12, wherein
the layer structure where the first i-type InP cladding region and the n-type InGaAsP are sequentially laminated on the substrate is formed by wafer-bonding an SiO₂ surface on an Si substrate and surfaces of the n-type InGaAsP and the i-type InP layer sequentially laminated on InP.

14. The method of manufacturing a light reception device according to claim 12, wherein
after removing the part of the i-type InP insertion layer, a thickness of the i-type InP insertion layer ranges from 50 nm to 100 nm.

15. The method of manufacturing a light reception device according to claim 12, wherein
the n-type InGaAsP waveguide core is lattice-matched to InP and has a composition in which light guided through the n-type waveguide core is not absorbed.

16. The method of manufacturing a light reception device according to claim 12, wherein
the InGaAsP of the p-type diffusion barrier layer has a bandgap ranging from 0.85 eV to 0.9 eV.

17. The method of manufacturing a light reception device according to claim 12, wherein
the InGaAsP of the n-type waveguide core has an energy gap ranging from 0.81 eV to 0.95 eV.
